(19) United States
(12) Patent Application Publication
(10) Pub. No.: US 2013/0222007 A1
(43) Pub. Date: Aug. 29, 2013

(54) POWER SUPPLY TEST SYSTEM

(71) Applicants: ZHI-YONG GAO, (US); HAI-YI JI, (US); YU-LIN LIU, (US)

(72) Inventors: ZHI-YONG GAO, Wuhan City (CN); HAI-YI JI, Wuhan City (CN); YU-LIN LIU, Wuhan City (CN)

(21) Appl. No.: 13/632,257

(22) Filed: Oct. 1, 2012

(30) Foreign Application Priority Data
Feb. 28, 2012 (CN) 201210046651.5

(51) Int. Cl. G01R 31/40

(52) U.S. Cl. 324/764.01

(57) ABSTRACT

A power supply test system for testing the reliability of a power supply includes a controlling input module, a signal collecting module, a signal input module, an alarm module, and a display module. The controlling input module inputs a time signal and a test signal in the signal collecting module. The signal collecting module turns on the power supply according to the test signal. When the power supply is turned on, the power supply outputs a power on signal, the signal collecting module records the time the test starts. When the power supply breaks off, the power supply outputs a power off signal, the signal collecting module records the time the power supply breaks off and outputs an alarm signal. The alarm module receives alarm signal and alarms to indicate the test is over. The display module displays the time the test starts and the power supply breaks off.

### BACKGROUND

1. Technical Field

The present disclosure relates to a power supply test system for testing reliability of a power supply.

2. Description of Related Art

Computer power supplies are capable of converting alternating current into direct current. The reliability of a power supply is measured by comparing the input and output voltages of the power supplies. A power on test is an important test in determining the reliability of the power supply. A typical power on test keeps the computer running for a long period of time to analyze reliability of the power supply. However, the typical testing method cannot record an accurate time when the power supply breaks down.

Therefore there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an embodiment of a power supply test system, the power supply test system including a controlling input module, a signal input module, a signal collecting module, a decoding module, a display module, and an alarm module.

FIG. 2 is a circuit diagram of the controlling input module, the signal input module, the signal collecting module, and the alarm module of FIG. 1.

FIG. 3 is a circuit diagram of the decoding module and the display module of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

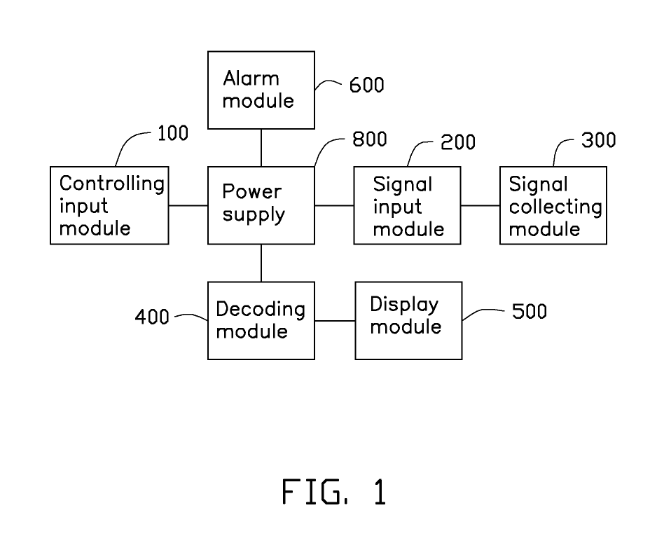

FIG. 1 illustrates a power supply test system in accordance with an embodiment. The power supply test system is adapted to test the reliability of a power supply 800. The power supply test system includes a controlling input module 100, a signal input module 200, a signal collecting module 300, a decoding module 400, a display module 500, and an alarm module 600. The controlling input module 100 is adapted to input a time signal and a test signal in the signal collecting module 300. The signal collecting module 300 turns on the power supply 800 according to the test signal. The power supply 800 is adapted to transmit a power on signal to the signal collecting module 300 via the signal input module 200. The signal collecting module 300 is adapted to record a time the test starts according to the time signal. When the power supply 800 breaks down, the power supply 800 transmits a breakdown signal to the signal collecting module 300 via the signal input module 200. The signal collecting module 300 records a time the power supply 800 breaks down. The signal collecting module 300 transmits an alarm signal to the alarm module 600. The alarm module 600 alarms to indicate the test is complete. The decoding module 400 decodes the time the test starts and the time the power supply 800 breaks down to digital signals which are displayed on the display module 500.

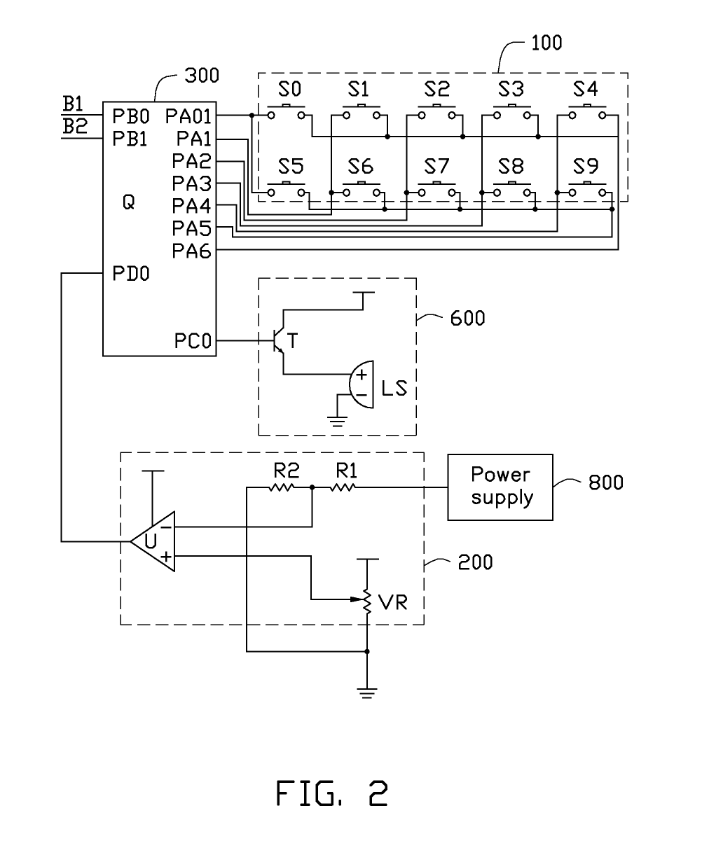

FIG. 2 illustrates the controlling input module 100, the signal input module 200, the signal collecting module 300, and the alarm module 600 in accordance with one embodiment. The controlling input module 100 includes a plurality of button switches S0-S9. The signal collecting module 300 includes a micro controller Q. The micro controller Q includes a plurality of time signal input terminals PA0, PA5, and PA6, a plurality of test signal input terminals PA1-PA4, an alarm signal output terminal PC0, a control signal input terminal PD0, a serial data output terminal PB0, and a clock signal output terminal PB1. First terminals of the button switches S0 and S5 are electrically connected to the time signal input terminal PA0. First terminals of the button switches S1 and S6 are electrically connected to the test signal input terminal PAL First terminals of the button switches S2 and S7 are electrically connected to the test signal input terminal PA2. First terminals of the button switches S3 and S8 are electrically connected to the test signal input terminal PA3. First terminals of the button switches S4 and S9 are electrically connected to the test signal input terminal PA4. Second terminals of the button switches S0-S4 are electrically connected to the time signal input terminal PA5. Second terminals of the button switches S5-S9 are electrically connected to the time signal input terminal PA6.

The signal input module 200 includes a comparator U, a first resistor R1, a second resistor R2, and a variable resistor VR. The variable resistor VR includes a first terminal, a second terminal, and an adjusting terminal A first terminal of the first resistor R1 is electrically connected to a power good signal output terminal of the power supply 800 to receive the power on signal. A second terminal of the first resistor R1 is grounded via the second resistor R2. An inverting input terminal of the comparator U is electrically connected to a connection point of the first and second resistors R1 and R2. A non-inverting input terminal of the comparator U is electrically connected to the adjusting terminal of the variable resistor VR. The first terminal of the variable resistor VR is adapted to receive a DC voltage. The second terminal of the variable resistor VR is grounded. An output terminal of the comparator U is electrically connected to the control signal input terminal PD0.

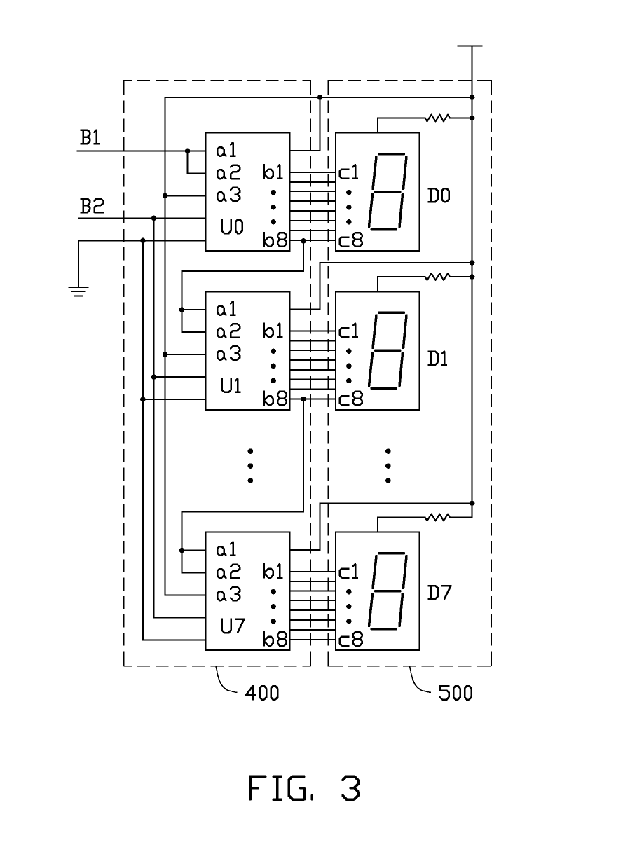

FIG. 3 illustrates the decoding module 400, and the display module 500 in accordance with one embodiment. The decoding module 400 includes a plurality of registers U0-U7. Each of the plurality of registers U0-U7 includes two serial data input terminals a1, a2, a clock signal input terminal a3, and a plurality of digital signal output terminals b1-b8. The serial data input terminals a1, a2 of the register U0 are electrically connected to the serial data output terminal PB0 of the micro controller Q. The serial data input terminals a1, a2 of the register U1 are electrically connected to the digital signal output terminal b8 of the register U0. The serial data input terminals a1, a2 of the register U2 are electrically connected to the digital signal output terminal b8 of the register U1. The serial data input terminals a1, a2 of the register U3 are electrically connected to the digital signal output terminal b8 of the register U2. The serial data input terminals a1, a2 of the register U4 are electrically connected to the digital signal output terminal b8 of the register U3. The serial data input terminals a1, a2 of the register U5 are electrically connected to the digital signal output terminal b8 of the register U4. The serial data input terminals a1, a2 of the register U6 are electrically connected to the digital signal output terminal b8 of the register U5. The serial data input terminals a1, a2 of the register U7 are electrically connected to the digital signal output terminal b8 of the register U6. The clock signal input terminals a3 of the plurality of registers U0-U7 are electrically connected to the clock signal output terminal PB1 of the micro controller Q.

The display module 500 includes a plurality of eight-segment numeral tubes D0-D7. Each of the plurality of eight-segment numeral tubes D0-D7 includes a plurality of digital signal input terminals c1-c8. The plurality of digital signal input terminals c1-c8 of the plurality of eight-segment numeral tubes D0-D7 are electrically connected to the plurality of digital signal output terminals b1-b8 of the plurality of registers U0-U7.

The alarm module 600 includes a transistor T and buzzer LS. A base of the transistor T is electrically connected to the alarm signal output terminal PC0 of the micro controller Q. An emitter of the transistor T is electrically connected to an anode of the buzzer LS. A collector of the transistor T receives the DC voltage. A cathode of the buzzer LS is grounded. In one embodiment, the transistor T is a NPN type transistor. The DC voltage is about +5V.

In a working state, the power supply 800 is electrically connected to the test system via the signal input module 200. The button switch S1 is pressed to start up the test system. The button switches S0 and S5 are pressed to set the time the test starts. The signal collecting module 300 turns on the power supply 800 according to the test signal when the time the test starts is achieved. The power good signal output terminal of the power supply 800 transmits a high voltage level power on signal to the signal input module 200. A voltage level at the inverting input terminal of the comparator U is higher than a voltage level at the non-inverting input terminal of the comparator U. The output terminal of the comparator U transmits a low voltage level control signal to the signal collecting module 300. The signal collecting module 300 determines the test starts and records the time the test starts. When the power supply 800 breaks down during the test, the power good signal output terminal of the power supply 800 transmits a low voltage level power off signal to the signal input module 200. A voltage level at the inverting input terminal of the comparator U is lower than a voltage level at the non-inverting input terminal of the comparator U. The output terminal of the comparator U transmits a high voltage level control signal to the signal collecting module 300. The signal collecting module 300 determines the test is over and records the time the power supply 800 breaks down. The signal collecting module 300 transmits a high voltage level alarm signal to the alarm module 600 via the alarm signal output terminal PC0. A base of the transistor T receives the high voltage level alarm signal. The transistor T turns on. The emitter of the transistor T transmits a high voltage level driving signal to the buzzer LS. The buzzer LS is activated to alarm. During the test, the decoding module 400 decodes the time the test starts and the time the power supply 800 breaks down to digital signals which are displayed on the display module 500.

In one embodiment, the button switch S0 is used to set hour information of the time the test starts. The button switch S5 is used to set minute information of the time the test starts. The test system is not limited to test a single power supply 800. A plurality of power supplies could be tested by electrically connecting power good signal output terminals of the power supplies to the first terminal of the first resistor R1. One of the button switches S1-S4 and S6-S9 are pressed to select a desired power supply to test. The eight-segment numeral tubes D0 and D1 are used to display the digital signals of hour information. The eight-segment numeral tubes D3 and D4 are used to display the digital signals of minute information. The eight-segment numeral tubes D6 and D7 are used to display the digital signals of second information. The eight-segment numeral tube D2 is used to display a decimal point between the digital signals of hour information and minute information. The eight-segment numeral tube D5 is used to display a decimal point between the digital signals of minute information and second information.

Even though numerous characteristics and advantages of the present disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A power supply test system for testing reliability of a power supply, the power supply test system comprising:
a controlling input module for inputting a time signal and a test signal;
a signal collecting module for receiving the time signal and the test signal and turning on the power supply according to the test signal;
a signal input module electrically connected to the power supply and the signal collecting module;
an alarm module; and
a display module, wherein when the power supply is turned on, the power supply outputs a power on signal to the signal collecting module via the signal input module, the signal collecting module records a time the test starts; when the power supply breaks off, the power supply outputs a power off signal to the signal collecting module via the signal input module, the signal collecting module records the time the power supply breaks off and outputs an alarm signal; the alarm module receives the alarm signal and alarming to indicate the test is over; and the display module displays the time the test starts and the time the power supply breaks off.

2. The power supply test system of claim 1, wherein the controlling input module comprises at least a first switch, a second switch, and a third switch; the signal collecting module comprises a first time signal input terminal, a second time signal input terminal, a third time signal input terminal, and a test signal input terminal; first terminals of the first and second switches are electrically connected to the first time signal input terminal; second terminals of the first and second switches are electrically connected to the second and third time signal input terminal respectively; a first terminal of the third switch is electrically connected to the test signal input terminal; and a second terminal of the third switch is electrically connected to the second time signal input terminal.

3. The power supply test system of claim 1, wherein the signal input module comprises a comparator, a first resistor, a second resistor, and a variable resistor; the variable resistor comprises a first terminal, a second terminal, and an adjusting terminal; a first terminal of the first resistor is electrically connected to a power good signal output terminal of the power supply to receive the power on signal; a second terminal of the first resistor is grounded via the second resistor; an inverting input terminal of the comparator is electrically connected to a connection point of the first and second resistors; a non-inverting input terminal of the comparator is electrically connected to the adjusting terminal of the variable resistor; the first terminal of the variable resistor is adapted to receive a DC voltage; and the second terminal of the variable resistor is grounded.

4. The power supply test system of claim 3, wherein the DC voltage is about +5V.

5. The power supply test system of claim 3, wherein the signal collecting module further comprises an alarm signal output terminal; the alarm module comprises a transistor and buzzer; a base of the transistor is electrically connected to the alarm signal output terminal; an emitter of the transistor is electrically connected to an anode of the buzzer; a collector of the transistor receives the DC voltage; and a cathode of the buzzer is grounded.

6. The power supply test system of claim 5, wherein the transistor is an NPN type transistor.

7. The power supply test system of claim 1, further comprising a decoding module electrically connected to the signal collecting module and the display module; the signal collecting module further comprises a serial data output terminal; the decoding module comprises at least a first register and a second register; each of the first and second registers comprises two serial data input terminals and a plurality of digital signal output terminals; the two serial data input terminals of the first register are electrically connected to the serial data output terminal; and the two serial data input terminals of the second register are electrically connected to one digital signal output terminal of the first register.

8. The power supply test system of claim 7, wherein the display module comprises at least a first numeral tube and a second numeral tube; each of the first and second numeral tubes comprises a plurality of digital signal input terminals; the plurality of digital signal input terminals of the first numeral tube are electrically connected to the plurality of digital signal output terminals of the first register; and the plurality of digital signal input terminals of the second numeral tube are electrically connected to the plurality of digital signal output terminals of the second register.

9. A power supply test system for testing reliability of a power supply, the power supply test system comprising:
a controlling input module for inputting a time signal and a test signal;
a signal collecting module for receiving the time signal and the test signal and turning on the power supply according to the test signal;
a signal input module electrically connected to the power supply and the signal collecting module;
an alarm module;
a decoding module; and
a display module, wherein when the power supply is turned on, the power supply outputs a power on signal to the signal collecting module via the signal input module, the signal collecting module records the time the test starts; when the power supply breaks off, the power supply outputs a power off signal to the signal collecting module via the signal input module, the signal collecting module records the time the power supply breaks off and outputs an alarm signal; the alarm module receives the alarm signal and alarming to indicate the test is over; the decoding module decodes the time the test starts and the time the power supply breaks off to digital signals; and the display module displays the time the test starts and the time the power supply breaks off.

10. The power supply test system of claim 9, wherein the controlling input module comprises at least a first switch, a second switch, and a third switch; the signal collecting module comprises a first time signal input terminal, a second time signal input terminal, a third time signal input terminal, and a test signal input terminal; first terminals of the first and second switches are electrically connected to the first time signal input terminal; second terminals of the first and second switches are electrically connected to the second and third time signal input terminal respectively; a first terminal of the third switch is electrically connected to the test signal input terminal; and a second terminal of the third switch is electrically connected to the second time signal input terminal.

11. The power supply test system of claim 9, wherein the signal input module comprises a comparator, a first resistor, a second resistor, and a variable resistor; the variable resistor comprises a first terminal, a second terminal, and an adjusting terminal; a first terminal of the first resistor is electrically connected to a power good signal output terminal of the power supply to receive the power on signal; a second terminal of the first resistor is grounded via the second resistor; an inverting input terminal of the comparator is electrically connected to a connection point of the first and second resistors; a non-inverting input terminal of the comparator is electrically connected to the adjusting terminal of the variable resistor; the first terminal of the variable resistor is adapted to receive a DC voltage; and the second terminal of the variable resistor is grounded.

12. The power supply test system of claim 11, wherein the DC voltage is about +5V.

13. The power supply test system of claim 11, wherein the signal collecting module further comprises an alarm signal output terminal; the alarm module comprises a transistor and buzzer; a base of the transistor is electrically connected to the alarm signal output terminal; an emitter of the transistor is electrically connected to an anode of the buzzer; a collector of the transistor receives the DC voltage; and a cathode of the buzzer is grounded.

14. The power supply test system of claim 13, wherein the transistor is an NPN type transistor.

15. The power supply test system of claim 9, wherein the signal collecting module further comprises a serial data output terminal; the decoding module comprises at least a first register and a second register; each of the first and second registers comprises two serial data input terminals and a plurality of digital signal output terminals; the two serial data input terminals of the first register are electrically connected to the serial data output terminal; and the two serial data input terminals of the second register are electrically connected to one digital signal output terminal of the first register.

16. The power supply test system of claim 15, wherein the display module comprises at least a first numeral tube and a second numeral tube; each of the first and second numeral tubes comprises a plurality of digital signal input terminals; the plurality of digital signal input terminals of the first numeral tube are electrically connected to the plurality of digital signal output terminals of the first register; and the plurality of digital signal input terminals of the second numeral tube are electrically connected to the plurality of digital signal output terminals of the second register.
